(19) United States
(12) Patent Application Publication
(10) Pub. No.: US 2025/0349713 A1
(43) Pub. Date: Nov. 13, 2025

(54) SEMICONDUCTOR INTEGRATED CIRCUIT DEVICE

(71) Applicant: Socionext Inc., Kanagawa (JP)

(72) Inventor: Toshio HINO, Yokohama-shi (JP)

(21) Appl. No.: 19/277,163

(22) Filed: Jul. 22, 2025

Related U.S. Application Data
(63) Continuation of application No. PCT/JP2024/005197, filed on Feb. 15, 2024.

(30) Foreign Application Priority Data
Feb. 20, 2023 (JP) 2023-024428

(51) Int. Cl. H01L 23/528; H10D 84/83; H10D 89/10

(52) U.S. Cl. CPC H01L 23/528; H10D 84/832; H10D 89/10

(57) ABSTRACT

In a semiconductor integrated circuit device, a standard cell includes: an active region forming the channel, source, and drain of a transistor; and a first power line extending in the X direction. The first power line, formed on the back side of the transistor, has an overlap with the active region in planar view. A second power line extending in the Y direction is formed in an interconnect layer located below the first power line. The second power line is connected to the first power line through a via and has an overlap with the active region in planar view.

### CROSS-REFERENCE TO RELATED APPLICATIONS

This is a continuation of International Application No. PCT/JP2024/005197 filed on Feb. 15, 2024, which claims priority to Japanese Patent Application No. 2023-024428 filed on Feb. 20, 2023. The entire disclosures of these applications are incorporated by reference herein.

### BACKGROUND

The present disclosure relates to a semiconductor integrated circuit device.

As a method for forming a semiconductor integrated circuit on a semiconductor substrate, a standard cell method is known. The standard cell method is a method in which basic units (e.g., inverters, latches, flipflops, and full adders) having specific logical functions are prepared in advance as standard cells, and a plurality of such standard cells are placed on a semiconductor substrate and connected through interconnects, whereby an LSI chip is designed.

Also, as for a transistor, which is a basic constituent of an LSI, improvement in integration degree, reduction in operating voltage, and improvement in operating speed have been achieved by reducing (scaling) the gate length. In recent years, however, increase in off current due to excessive scaling and the resulting significant increase in power consumption have raised a problem. To solve this problem, three-dimensional transistors, of which the transistor structure has changed from the conventional planar structure to a three-dimensional structure, have been vigorously studied. A nanosheet FET is one example of such three-dimensional transistors.

US Patent Application Publication No. 2022/0037252 discloses, for further higher integration, a technique of providing interconnects in a plurality of layers on the back of a substrate right under transistors so as to lay power lines and signal lines.

In the technique of the cited patent document, however, since a region for laying signal lines is provided on the back side of the substrate, a region for laying power lines is not sufficiently secured, causing decrease in power supply capability, whereby problems such as a power supply voltage drop and a resultant circuit malfunction may occur.

Also, the technique of the cited patent document has a problem that the design becomes complicate and difficult because signal lines are provided on both the surface side of the substrate above transistors and the back side of the substrate.

An objective of the present disclosure is presenting a layout structure of a semiconductor integrated circuit device having interconnects in a plurality of layers on the back side of transistors, in which power supply capability can be sufficiently secured.

### SUMMARY

According to the first mode of the disclosure, a semiconductor integrated circuit device includes a plurality of cell rows each including a plurality of standard cells arranged in a first direction, wherein a first cell row as one of the plurality of cell rows includes a first standard cell, the first standard cell includes a first active region forming a channel, source, and drain of a first transistor of a first conductivity type, and including a first nanosheet extending in the first direction as the channel, and a first power line formed on the back side of the first transistor, extending in the first direction, having an overlap with the first active region in planar view, and supplying a first power supply voltage, the semiconductor integrated circuit device further includes a second power line formed in an interconnect layer located below the first power line, extending in a second direction perpendicular to the first direction, and supplying the first power supply voltage, and the second power line has an overlap with the first active region in planar view, and is connected to the first power line through a via.

According to the above mode, in the semiconductor integrated circuit device, the first standard cell includes: a first active region forming the channel, source, and drain of a first transistor; and a first power line extending in the first direction. The first power line, formed on the back side of the first transistor, has an overlap with the first active region in planar view. Also, a second power line extending in the second direction is formed in an interconnect layer located below the first power line. The second power line is connected to the first power line through a via and has an overlap with the first active region in planar view. With this, since power lines can be placed with high density on the back side of the transistor, the power supply capability can be sufficiently secured.

According to the present disclosure, in a semiconductor integrated circuit device having interconnects in a plurality of layers on the back side of transistors, power supply capability can be sufficiently secured.

### BRIEF DESCRIPTION OF THE DRAWINGS

FIG. 1 is a plan view showing a layout example of a circuit block provided in a semiconductor integrated circuit device according to an embodiment.

FIG. 2 is a plan view showing a layout structure example of an inverter cell included in the semiconductor integrated circuit device according to the embodiment.

FIGS. 3A and 3B are cross-sectional views of the inverter cell of FIG. 2.

FIG. 4 is a circuit diagram of the inverter cell shown in FIGS. 2 and 3A-3B.

FIGS. 5A and 5B show another configuration example of the semiconductor integrated circuit device according to the embodiment.

FIGS. 6A-6B are plan views showing layout structure examples of cells included in the semiconductor integrated circuit device according to the embodiment, where FIG. 6A shows a 2-input NAND cell and FIG. 6B shows a 2-input NOR cell.

FIG. 7A is a circuit diagram of the 2-input NAND cell, and FIG. 7B is a circuit diagram of the 2-input NOR cell.

FIG. 8 is a partial enlarged view of the layout example of FIG. 1.

FIGS. 9A and 9B are plan views showing block layout examples according to alterations of the embodiment.

FIGS. 10A-10C are views showing layout structures of cells constituting the block layouts of FIGS. 9A-9B, where FIG. 10A shows an inverter cell, FIG. 10B shows a 2-input NAND cell, and FIG. 10C shows a 2-input NOR cell.

### DETAILED DESCRIPTION

An embodiment of the present disclosure will be described hereinafter with reference to the accompanying drawings. In the following embodiment, it is assumed that the semiconductor integrated circuit device includes a plurality of standard cells (hereinafter simply called cells as appropriate), and at least some of the standard cells include nanosheet field effect transistors (FETs). The nanosheet FET is a FET using a thin sheet (nanosheet) through which a current flows. Such a nanosheet is formed of silicon, for example. Note however that, in the present disclosure, the transistors included in the standard cells are not limited to nanosheet FETs.

As used herein, “VDD” and “VSS” refer to the power supply voltages or the power supplies themselves. Also, as used herein, an expression indicating that sizes such as widths are identical, like the “same wiring width,” is to be understood as including a range of manufacturing variations.

### (Configuration of Circuit Block)

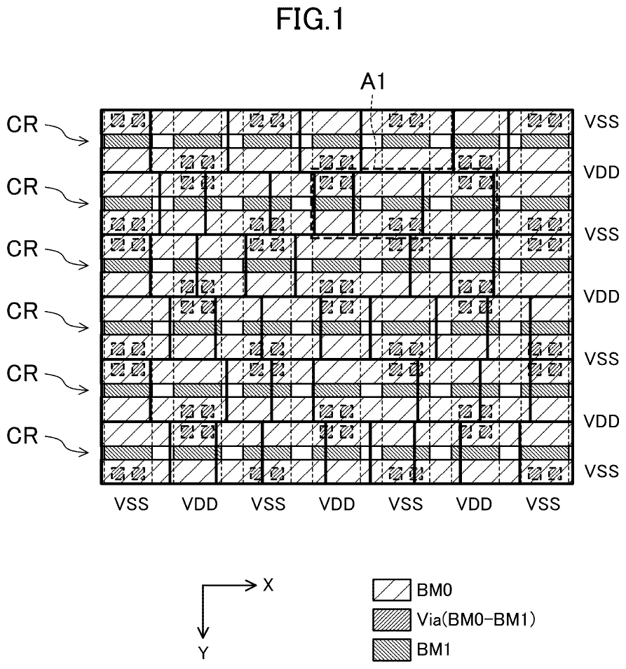

FIG. 1 is a plan view showing a layout example of a circuit block provided in a semiconductor integrated circuit device according to an embodiment. The block layout of FIG. 1 is constituted by placement of standard cells. In FIG. 1, only the cell frames of standard cells and power lines are illustrated, omitting the internal structures of the standard cells and interconnects between the standard cells. In this embodiment, power lines are formed in a backside metal 0 (BM0) layer and a backside metal 1 (BM1) layer that are interconnect layers provided on the back of a semiconductor chip in which transistors are formed. The BM1 layer is located under the BM0 layer, i.e., located farther with respect to the transistors.

Note that, in the plan views such as FIG. 1, the horizontal direction in the figure is hereinafter referred to as an X direction (corresponding to the first direction), the vertical direction in the figure as a Y direction (corresponding to the second direction), and the direction perpendicular to the substrate plane as a Z direction. Also, hereinafter, the same components are denoted by the same reference characters, and description of such components may not be repeated.

In the layout of FIG. 1, a plurality of cells arranged in the X direction constitute a cell row CR, and a plurality of cell rows CR (six rows in FIG. 1) are arranged in the Y direction. The plurality of cells include cells having logical functions such as an inverter, a NAND gate, and a NOR gate.

In each cell, power lines are formed on both ends of the cell in the Y direction in the BM0 layer, through which power supply voltages VDD and VSS are supplied to the cell from outside. The cell rows CR are placed in a vertically flipped position every other row. Along the boundaries of adjacent cell rows CR, power lines supplying VDD are contiguous with each other in the Y direction, and power lines supplying VSS are contiguous with each other in the Y direction. That is, in the BM0 layer, power lines extending in the X direction are formed: power lines supplying VDD and power lines supplying VSS are placed alternately in the Y direction.

In the BM1 layer, power lines extending in the Y direction are formed: power lines supplying VDD and power lines supplying VSS are placed alternately in the X direction. The power lines supplying VDD formed in the BM0 layer and the BM1 layer are mutually connected through vias formed at positions overlapping each other in planar view. The power lines supplying VSS formed in the BM0 layer and the BM1 layer are mutually connected through vias formed at positions overlapping each other in planar view. That is, for each of the power supply voltage VDD and the power supply voltage VSS, a mesh network of power lines is formed in the BM0 and BM1 layers, whereby power supply capability is strengthened.

The power lines in the BM1 layer are laid at the time of block layout design after the placement of standard cells. In this embodiment, in the BM1 layer, the power lines supplying VDD and the power lines supplying VSS are alternately placed, and the spacing between adjacent power lines is minimum under constraints in the manufacturing processes. With this, since power lines can be maximally placed in the BM1 layer, the power supply voltage drop can be effectively prevented or reduced, whereby problems such as a malfunction of the circuit can be avoided.

Also, the power lines in the BM1 layer overlap the cells in planar view. As will be described later, active regions of the cells overlap the power lines in the BM1 layer. The active region as used herein refers to a region forming the channel, source, and drain of a transistor. An active region constituting a nanosheet FET has a nanosheet as the channel. In the active region, portions that are to be the source and the drain located on the sides of the nanosheet are formed by epitaxial growth from the nanosheet.

On the other hand, in the circuit block of FIG. 1, signal lines connecting the cells are not placed in the BM0 layer or the BM1 layer, but laid only in interconnect layers on the surface side of the substrate located above transistors. This makes the design of signal lines easy.

Note that, one or a plurality of interconnect layers may further be placed under the BM1 layer to lay power lines in such an interconnect layer. This can further strengthen power lines. In this case, the direction in which power lines extend may preferably be changed alternately every interconnect layer, like placing power lines in the X direction in a BM2 layer and placing power lines in the Y direction in a BM3 layer, for example.

### <Inverter Cell>

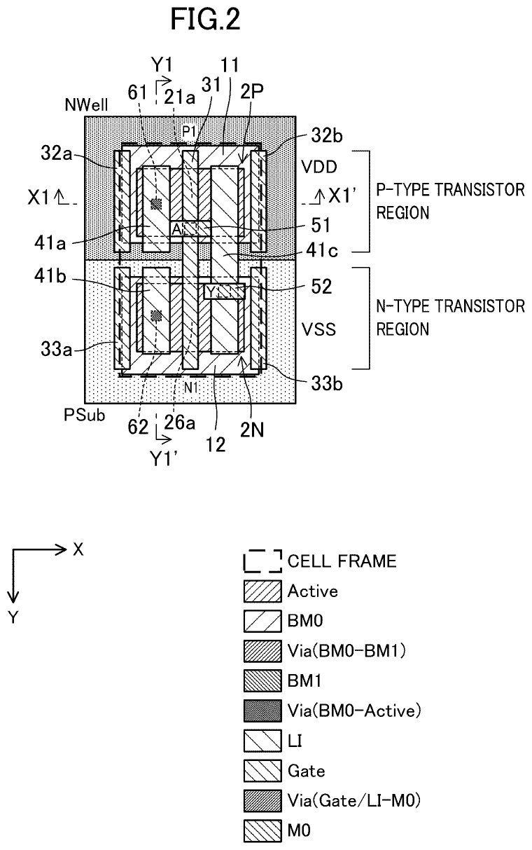

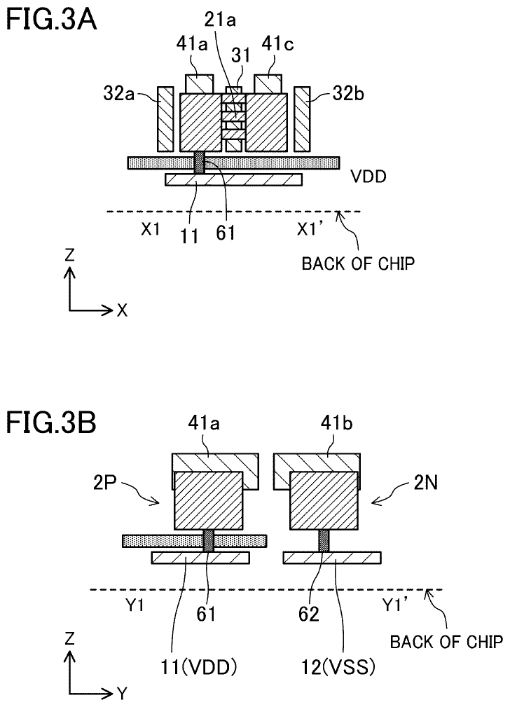

FIGS. 2 and 3A-3B are views showing an example of the layout structure of an inverter cell included in the semiconductor integrated circuit device according to the embodiment. FIG. 2 is a plan view, and FIGS. 3A and 3B are cross-sectional views, where FIG. 3A shows a cross section taken along horizontal line X1-X1′ in planar view and FIG. 3B shows a cross section taken along vertical line Y1-Y1′ in planar view.

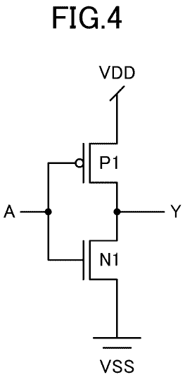

FIG. 4 is a circuit diagram of the inverter cell shown in FIGS. 2 and 3A-3B. As shown in FIG. 4, the inverter cell has a p-type transistor P1 and an n-type transistor N1.

Power lines 11 and 12 extending in the X direction are formed in the BM0 interconnect layer provided on the back of the semiconductor chip in which transistors are formed. The power line 11 supplies the power supply voltage VDD, and the power line 12 supplies the power supply voltage VSS. The spacing between the power lines 11 and 12 in the Y direction is minimum under constraints in the manufacturing processes. The power lines 11 and 12 are shared with other cells in the cell row including the inverter cell, to serve as power lines extending in the X direction. Also, each of the power lines 11 and 12 is shared with a cell row adjacent in the Y direction.

In a p-type transistor region on an n-type well (NWell), an active region 2P forming the channel, source, and drain of a p-type transistor is formed. The active region 2P overlaps the power line 11 in planar view.

In the p-type transistor region, the p-type transistor P1 is formed. The transistor P1 has nanosheets 21a of a structure of three sheets lying one above another and extending in the X direction. That is, the transistor P1 is a nanosheet FET. In the active region 2P, a portion that is to be the source of the transistor P1 is connected to the power supply 11 through a via 61.

In an n-type transistor region on a p-type substrate (Psub), an active region 2N forming the channel, source, and drain of an n-type transistor is formed. The active region 2N overlaps the power line 12 in planar view. Note that the n-type transistor region may be formed on a p-type well.

In the n-type transistor region, the n-type transistor N1 is formed. The transistor N1 has nanosheets 26a of a structure of three sheets lying one above another and extending in the X direction. That is, the transistor N1 is a nanosheet FET. In the active region 2N, a portion that is to be the source of the transistor N1 is connected to the power supply 12 through a via 62.

A gate interconnect 31 is formed to extend in the Y direction from the p-type transistor region over to the n-type transistor region. The gate interconnect 31 surrounds the peripheries of the nanosheets 21a of the transistor P1 and the nanosheets 26a of the transistor N1 in the Y and Z directions via gate insulating films (not shown). The gate interconnect 31 corresponds to the gates of the transistors P1 and N1.

In the p-type transistor region, dummy gate interconnects 32a and 32b are formed on the side portions of the cell frame CF in the X direction. In the n-type transistor region, dummy gate interconnects 33a and 33b are formed on the side portions of the cell frame CF in the X direction. The dummy gate interconnects 32a and 33a are shared with the cell placed on the left in the figure, and the dummy gate interconnects 32b and 33b are shared with the cell placed on the right in the figure.

Local interconnects 41a, 41b, and 41c extending in the Y direction are formed in a local interconnect layer. The local interconnect 41a is connected to the portion that is to be the source of the transistor P1 in the active region 2P. The local interconnect 41b is connected to the portion that is to be the source of the transistor N1 in the active region 2N. The local interconnect 41c, extending from the p-type transistor region over to the n-type transistor region, is connected to a portion that is to be the drain of the transistor P1 in the active region 2P and a portion that is to be the drain of the transistor N1 in the active region 2N.

Metal interconnects 51 and 52 extending in the X direction are formed in an MO interconnect layer that is a metal interconnect layer located above the local interconnect layer. The metal interconnect 51 is connected to the gate interconnect 31 through a via, and the metal interconnect 52 is connected to the local interconnect 41c through a via. The metal interconnect 51 corresponds to a node A, and the metal interconnect 52 corresponds to a node Y.

In the inverter cell shown in FIGS. 2 and 3A-3B, the power line 11 supplying VDD and the power line 12 supplying VSS are placed with a minimum spacing between them in the Y direction in the BM0 layer. The power line 11 overlaps the active region 2P constituting the p-type transistor in planar view, and the power line 12 overlaps the active region 2N constituting the n-type transistor in planar view. In the BM0 layer, no interconnect can be laid between the power line 11 and the power line 12. Since this can maximize the width of the power lines in the cell, the power supply voltage drop can be prevented or reduced, whereby problems such as a malfunction of the circuit can be avoided.

Also, in the block layout design, power lines extending in the Y direction are placed in the BM1 layer located under the BM0 layer. The power line 11 is connected to a VDD power line in the BM1 layer through a via, and the power line 12 is connected to a VSS power line in the BM1 layer through a via.

While the power lines 11 and 12 are formed in the interconnect layer provided on the back of the semiconductor chip in the above description, the configuration is not limited to this. According to the present disclosure, it is only required for the power lines to be formed on the back side of the transistors. The “back side of the transistors” as used herein refers to the side, with respect to the transistors, opposite to the side on which the local interconnects, the metal interconnects, and the like connected to the transistors are stacked one upon another.

Also, the power lines 11 and 12 may be formed in a plurality of interconnect layers.

### Other Configuration Example

The power lines on the back side of the transistors described above may also be formed using a semiconductor chip other than the semiconductor chip in which the transistors are formed.

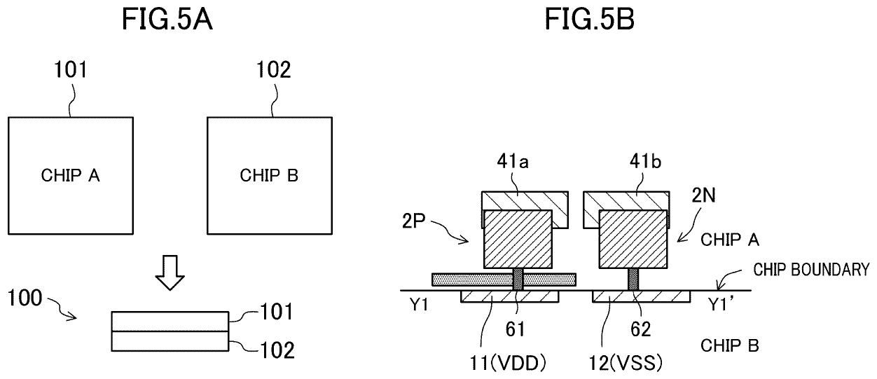

FIG. 5A shows another configuration example of the semiconductor integrated circuit device according to the embodiment. A semiconductor integrated circuit device 100 shown in FIG. 5A is constituted by a first semiconductor chip 101 (chip A) and a second semiconductor chip 102 (chip B) stacked one upon the other. In the chip A, standard cells including the above-described inverter cell and the like are placed. In the chip B, power lines are formed in an interconnect layer provided on the surface. The chip B is bonded to the back of the chip A using bumps and the like.

FIG. 5B shows a cross section of this configuration example taken along line Y1-Y1′ in the inverter cell of FIG. 2. As shown in FIG. 5B, the power line 11 supplying VDD and the power line 12 supplying VSS are formed in the interconnect layer provided on the surface of the chip B. The power line 11 is connected to the active region 2P in the chip A through the via 61, and the power line 12 is connected to the active region 2N in the chip A through the via 62.

With this configuration example, also, effects similar to those in the inverter cell described above can be obtained. Note that, in this configuration example, also, the power lines 11 and 12 may be formed in a plurality of interconnect layers. Note also that, in this configuration example, power lines in the BM1 layer and its underlying layer are also formed in the chip B.

### <2-Input NAND Cell and 2-Input NOR Cell>

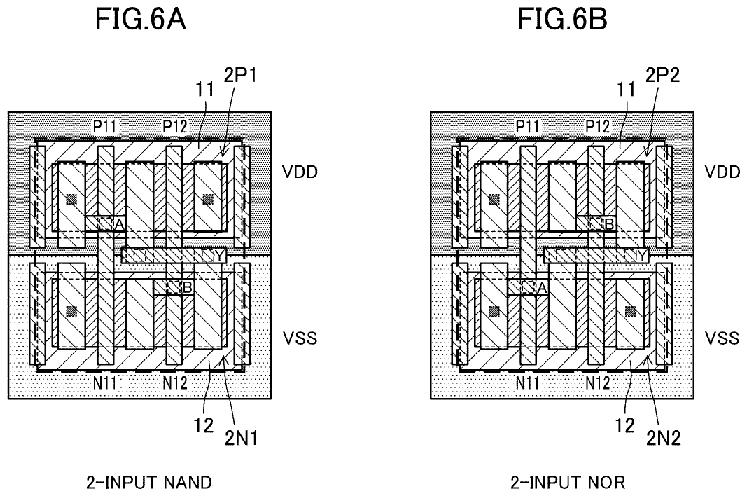

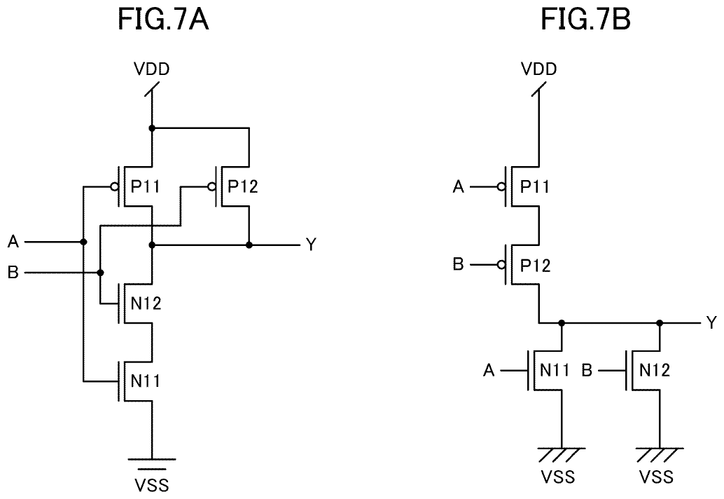

FIGS. 6A-6B are plan views showing layout structure examples of cells included in the semiconductor integrated circuit device according to the embodiment, where FIG. 6A shows a 2-input NAND cell and FIG. 6B shows a 2-input NOR cell. FIG. 7A is a circuit diagram of the 2-input NAND cell, and FIG. 7B is a circuit diagram of the 2-input NOR cell.

For the layout structures of FIGS. 6A-6B, description of configurations that can be easily known by analogy from the above description on the inverter cell and the circuit diagrams of FIGS. 7A-7B is omitted here.

In the 2-input NAND cell shown in FIG. 6A, the power line 11 supplying VDD and the power line 12 supplying VSS are placed with a minimum spacing between them in the Y direction in the BM0 layer. The power line 11 overlaps an active region 2P1 constituting a p-type transistor in planar view, and the power line 12 overlaps an active region 2N1 constituting an n-type transistor in planar view.

In the 2-input NOR cell shown in FIG. 6B, also, the power line 11 supplying VDD and the power line 12 supplying VSS are placed with a minimum spacing between them in the Y direction in the BM0 layer. The power line 11 overlaps an active region 2P2 constituting a p-type transistor in planar view, and the power line 12 overlaps an active region 2N2 constituting an n-type transistor in planar view.

In the 2-input NAND cell shown in FIG. 6A and the 2-input NOR cell shown in FIG. 6B, also, since the width of the power lines in the cell can be maximized, the power supply voltage drop can be prevented or reduced, whereby problems such as a malfunction of the circuit can be avoided.

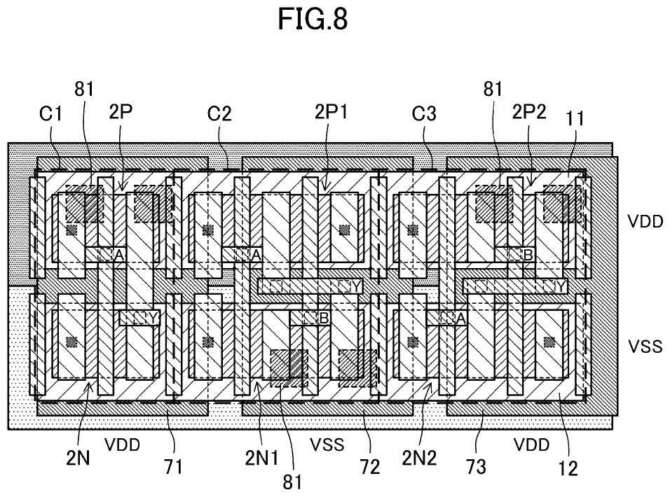

FIG. 8 is an enlarged view of part A1 in the block layout of FIG. 1. In the configuration of FIG. 8, an inverter cell C1, a 2-input NAND cell C2, and a 2-input NOR cell C3 are arranged in this order from the left in the figure. The layout structures of the cells C1, C2, and C3 are as already described above.

In the BM1 layer, power lines 71, 72, and 73 extending in the Y direction are formed. The power lines 71 and 73 supply the power supply voltage VDD, and the power line 72 supplies the power supply voltage VSS. The power lines 71 and 73 are connected to the power line 11 through vias 81, and the power line 72 is connected to the power line 12 through vias 81.

In the inverter cell C1, the active regions 2P and 2N overlap the power line 71 in planar view. In the 2-input NAND cell C2, the active regions 2P1 and 2N1 overlap the power lines 71 and 72 in planar view. In the 2-input NOR cell C3, the active regions 2P2 and 2N2 overlap the power lines 72 and 73 in planar view.

As shown in FIG. 8, the inverter cell C1 includes the active region 2P and the power line 11 extending in the X direction. The power line 11, formed on the back side of transistors, has an overlap with the active region 2P in planar view. Also, the power line 71 extending in the Y direction is formed in the interconnect layer located below the power line 11. The power line 71 is connected to the power line 11 through the vias 81 and has an overlap with the active region 2P in planar view.

The 2-input NAND cell C2 includes the active region 2N1 and the power line 12 extending in the X direction. The power line 12, formed on the back side of transistors, has an overlap with the active region 2N1 in planar view. Also, the power line 72 extending in the Y direction is formed in the interconnect layer located below the power line 12. The power line 72 is connected to the power line 12 through the vias 81 and has an overlap with the active region 2N1 in planar view.

The 2-input NOR cell C3 includes the active region 2P2 and the power line 11 extending in the X direction. The power line 11, formed on the back side of transistors, has an overlap with the active region 2P2 in planar view. Also, the power line 73 extending in the Y direction is formed in the interconnect layer located below the power line 11. The power line 73 is connected to the power line 11 through the vias 81 and has an overlap with the active region 2P2 in planar view.

As described above, according to this embodiment, since power lines can be placed with high density on the back side of transistors, the power supply capability can be sufficiently secured.

### (Alterations)

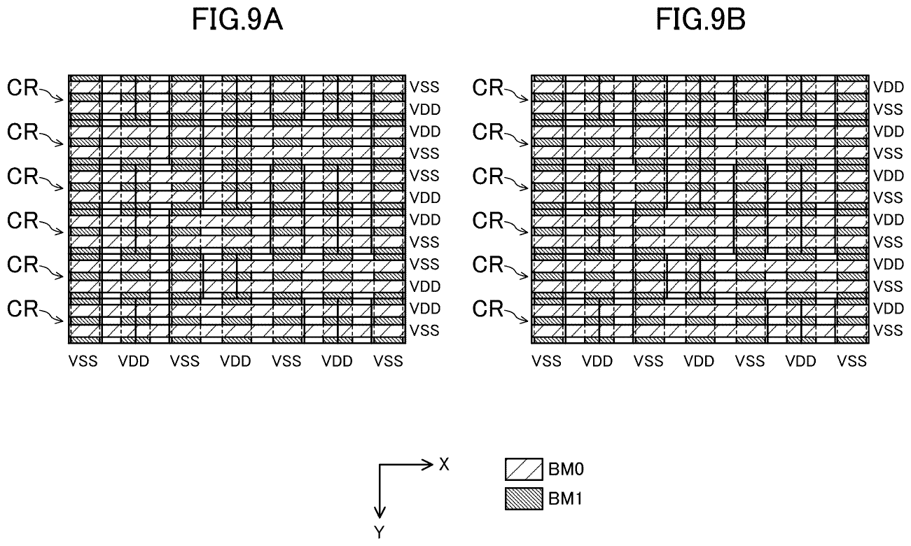

FIGS. 9A-9B are plan views showing block layout examples according to alterations of the embodiment. In FIGS. 9A-9B, as in the layout of FIG. 1, power lines supplying VDD formed in the BM0 layer and the BM1 layer are mutually connected through vias formed at positions overlapping each other in planar view, and power lines supplying VSS formed in the BM0 layer and the BM1 layer are mutually connected through vias formed at positions overlapping each other in planar view, although illustration of such vias is omitted.

In the block layout shown in FIG. 9A, the power lines in the BM0 layer are not shared between adjacent cell rows in the Y direction. Also, in the BM0 layer, the spacing between the power lines supplying VDD and the power lines supplying VSS is minimum under constraints in the manufacturing processes.

In FIG. 9B, any cell rows are not flipped in the Y direction, all placed in the same orientation. Also, as in FIG. 9A, the power lines in the BM0 layer are not shared between adjacent cell rows in the Y direction. In the BM0 layer, the spacing between the power lines supplying VDD and the power lines supplying VSS is minimum under constraints in the manufacturing processes.

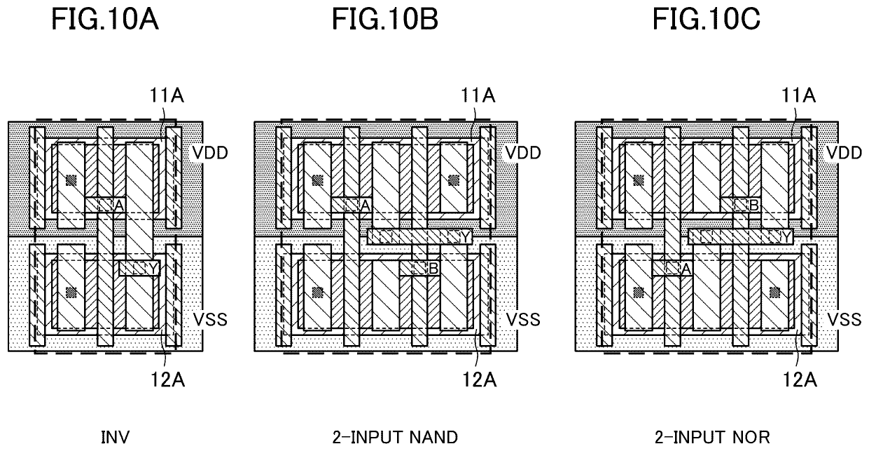

FIGS. 10A-10C are views showing layout structures of cells constituting the block layouts of FIGS. 9A-9B, where FIG. 10A shows an inverter cell, FIG. 10B shows a 2-input NAND cell, and FIG. 10C shows a 2-input NOR cell.

The configuration of the inverter cell of FIG. 10A is basically similar to that of the inverter cell of FIG. 2, except that the width of power lines 11A and 12A in the Y direction is smaller than the width of the power lines 11 and 12 in the Y direction. Also, there are a spacing between the upper portion of the cell frame in the figure and the power line 11A and a spacing between the lower portion of the cell frame in the figure and the power line 12A. These spacings are each equivalent to a half of the minimum spacing under constraints in the processing processes. Also, in the configuration of FIG. 10A, the width of Nwell and Psub in the Y direction is smaller than the width of Nwell and Psub in the Y direction in the configuration of FIG. 2.

The configurations of the 2-input NAND cell of FIG. 10B and the 2-input NOR cell of FIG. 10C are basically similar to those of the 2-input NAND cell of FIG. 6A and the 2-input NOR cell of FIG. 6B, respectively, except that, as in the inverter cell, the width of the power lines 11A and 12A in the Y direction is smaller than the width of the power lines 11 and 12 in the Y direction. Also, there are a spacing between the upper portion of the cell frame in the figure and the power line 11A and a spacing between the lower portion of the cell frame in the figure and the power line 12A. These spacings are each equivalent to a half of the minimum spacing under constraints in the processing processes. Also, in the configurations of FIGS. 10B and 10C, the width of Nwell and Psub in the Y direction is smaller than the width of Nwell and Psub in the Y direction in the configurations of FIGS. 6A and 6B.

While the nanosheets have the structure of three sheets lying one above another and the cross-sectional shape of the sheet structure is illustrated as a rectangle in the above embodiment, the number of nanosheets, and the cross-sectional shape, of the sheet structure are not limited to these.

While nanosheet FETs are used as the transistors in the above embodiment, the type of the transistors is not limited to this. For example, fin FETs or other types of transistors may be used.

According to the present disclosure, in a semiconductor integrated circuit device having interconnects in a plurality of layers on the back side of transistors, a layout structure capable of securing power supply capability sufficiently is presented. It is therefore possible to achieve downsizing, and improvement in the performance, of the semiconductor integrated circuit device, for example.

1. A semiconductor integrated circuit device, comprising
a plurality of cell rows each including a plurality of standard cells arranged in a first direction,
wherein
a first cell row as one of the plurality of cell rows includes
a first standard cell,
the first standard cell includes
a first active region forming a channel, source, and drain of a first transistor of a first conductivity type, and including a first nanosheet extending in the first direction as the channel, and
a first power line formed on a back side of the first transistor, extending in the first direction, having an overlap with the first active region in planar view, and supplying a first power supply voltage,
the semiconductor integrated circuit device further includes
a second power line formed in an interconnect layer located below the first power line, extending in a second direction perpendicular to the first direction, and supplying the first power supply voltage, and
the second power line has an overlap with the first active region in planar view, and is connected to the first power line through a via.

2. The semiconductor integrated circuit device of claim 1, wherein
the first standard cell includes
a second active region forming a channel, source, and drain of a second transistor of a second conductivity type, and including a second nanosheet extending in the first direction as the channel, and
the second power line has an overlap with the second active region in planar view.

3. The semiconductor integrated circuit device of claim 1, comprising
a third power line formed in a same interconnect layer as the second power line, extending in the second direction, and supplying a second power supply voltage, wherein
the third power line has an overlap with the first active region in planar view.

4. The semiconductor integrated circuit device of claim 1, wherein
the first and second power lines are formed in interconnect layers provided in a first semiconductor chip in which the first active region is formed.

5. The semiconductor integrated circuit device of claim 1, wherein
the first and second power lines are formed in interconnect layers provided in a second semiconductor chip bonded to a back of a first semiconductor chip in which the first active region is formed.
